(19) United States
(12) Patent Application Publication
(10) Pub. No.: US 2025/0089534 A1
(43) Pub. Date: Mar. 13, 2025

(54) DISPLAY APPARATUS AND METHOD OF MANUFACTURING THE SAME

(71) Applicant: Samsung Display Co., Ltd., Yongin-si (KR)

(72) Inventor: Sungwoo Eo, Yongin-si (KR)

(21) Appl. No.: 18/823,057

(22) Filed: Sep. 3, 2024

(30) Foreign Application Priority Data
Sep. 13, 2023 (KR) 10-2023-0122044

(51) Int. Cl. H10K 59/80; H10K 59/12; H10K 102/00

(52) U.S. Cl. CPC H10K 59/873; H10K 59/1201; H10K 2102/311

(57) ABSTRACT

A display apparatus includes: a display panel having a folding area and a non-folding area; a first plate on one surface of the display panel and comprising a first area and a second area, wherein the first area corresponds to the folding area of the display panel, and the second area corresponds to the non-folding area of the display panel; and a cover layer between the first plate and the display panel and in direct contact with at least a portion of the first plate, wherein the first area of the first plate comprises a plurality of slits each having a length in a first direction parallel to a folding axis of the folding area and being at least partially covered by the cover layer, and a width of each of the plurality of slits in a second direction perpendicular to the first direction is 100 micrometers (μm) or less.

### CROSS-REFERENCE TO RELATED APPLICATION

The present application claims priority to and the benefit of Korean Patent Application No. 10-2023-0122044, filed on Sep. 13, 2023, in the Korean Intellectual Property Office, the entire disclosure of which is incorporated herein by reference.

### BACKGROUND

### 1. Field

Aspects of one or more embodiments relate to a display apparatus and a method of manufacturing the display apparatus.

### 2. Description of the Related Art

Recently, the uses of display apparatuses has diversified. To implement various uses of such a display apparatus, the display apparatus may desirably be flexible to be bent or folded. However, in a display apparatus, the strength of the display apparatus may be reduced as the weight and thickness of the display apparatus decrease. Accordingly, research and development on flexible display devices have been conducted, and such flexible display apparatuses may desirably be relatively lightweight and thin.

The above information disclosed in this Background section is only for enhancement of understanding of the background and therefore the information discussed in this Background section does not necessarily constitute prior art.

### SUMMARY

Aspects of one or more embodiments relate to a display apparatus and a method of manufacturing the display apparatus, and for example, to a display 1 apparatus with relatively improved impact resistance, and a method of manufacturing the display apparatus.

Aspects of one or more embodiments include a display apparatus with relatively improved impact resistance, and a method of manufacturing the display apparatus. However, these are merely example characteristics, and the scope of embodiments according to the present disclosure is not limited thereto.

Additional aspects will be set forth in part in the description which follows and, in part, will be apparent from the description, or may be learned by practice of the presented embodiments of the disclosure.

According to one or more embodiments, a display apparatus includes a display panel in which a folding area and a non-folding area are defined, a first plate on one surface of the display panel and including a first area and a second area, wherein the first area corresponds to the folding area of the display panel, and the second area corresponds to the non-folding area of the display panel, and a cover layer arranged between the first plate and the display panel and in direct contact with at least a portion of the first plate, wherein the first area of the first plate includes a plurality of slits each having a length in a first direction parallel to a folding axis of the folding area and being at least partially covered by the cover layer, and a width of each of the plurality of slits in a second direction perpendicular to the first direction is 100 μm or less.

According to some embodiments, the display apparatus may further include an upper adhesive layer arranged between the first plate and the display panel to be in direct contact with the first plate.

According to some embodiments, the upper adhesive layer may include an upper opening corresponding to the first area of the first plate, and a thickness of the cover layer may be less than a thickness of the upper adhesive layer.

According to some embodiments, a depth of each of the plurality of slits may be less than a thickness of the second area of the first plate.

According to some embodiments, the plurality of slits may be arranged in parallel and spaced apart from each other in the second direction.

According to some embodiments, the display apparatus may further include a second plate below the first plate, and a lower adhesive layer arranged between the first plate and the second plate and including a lower opening corresponding to the first area of the first plate.

According to some embodiments, the cover layer may include a plurality of cover patterns extending in the second direction perpendicular to the first direction and arranged to be spaced apart from each other in the first direction.

According to some embodiments, the cover layer may include a light-blocking material.

According to some embodiments, the cover layer may overlap the first area and the second area of the first plate.

According to some embodiments, the cover layer may include at least one of polyethylene terephthalate (PET), low-density polyethylene (LDPE), polyethylene (PE), polypropylene (PP), polyvinyl chloride (PVC), or polyvinylidene chloride (PVDC).

According to one or more embodiments, a method of manufacturing a display apparatus includes forming a display panel in which a folding area and a non-folding area are defined, and forming a first plate on one surface of the display panel and including a first area and a second area, wherein the first area corresponds to the folding area of the display panel, and the second area corresponds to the non-folding area of the display panel, wherein the forming of the first plate includes forming a plurality of slits each having a first preliminary width in the first area of the first plate, forming a cover layer on the plurality of slits, and applying heat to the cover layer to shrink the plurality of slits to have a first width that is less than the first preliminary width.

According to some embodiments, the heat applied to the cover layer may be at least about 60° C. but not more than about 170° C.

According to some embodiments, a difference between the first preliminary width and the first width may be at least about 20 μm but not more than about 200 μm.

According to some embodiments, the first width may be 50 μm or less.

According to some embodiments, each of the plurality of slits may have a length in a first direction in parallel to a folding axis of the folding area, and the first width may include a width in a second direction intersecting the first direction.

According to some embodiments, the cover layer may include a plurality of cover patterns arranged in the first direction and each having a length in the second direction.

According to some embodiments, the method may further include forming an upper adhesive layer on the first plate and having an opening corresponding to the first area of the first plate, wherein a thickness of the upper adhesive layer may be greater than a thickness of the cover layer.

According to some embodiments, a depth of each of the plurality of slits may be less than a thickness of the second area of the first plate.

According to some embodiments, the cover layer may include a light-blocking material.

According to some embodiments, the cover layer may include at least one of polyethylene terephthalate (PET), low-density polyethylene (LDPE), polyethylene (PE), polypropylene (PP), polyvinyl chloride (PVC), or polyvinylidene chloride (PVDC).

Other aspects, features, and characteristics other than those described above will now become more apparent from the following drawings, claims, and the detailed description of the disclosure.

### BRIEF DESCRIPTION OF DRAWINGS

The above and other aspects, features, and characteristics of certain embodiments of the disclosure will be more apparent from the following description taken in conjunction with the accompanying drawings, in which:

FIGS. 1 and 2 are perspective views each schematically illustrating a display apparatus according to some embodiments;

FIG. 3A is a schematic cross-sectional view of the display apparatus of FIG. 1, taken along a line I-l′ in FIG. 1;

FIG. 3B is a schematic cross-sectional view of a display apparatus according to some embodiments;

FIGS. 4A and 4B are enlarged views of a portion of a first plate and a cover layer, according to some embodiments;

FIG. 5 is a graph showing a comparison in tensile strength between a comparative example and an example;

FIG. 6 is a graph showing a test result of impact resistance according to slit width;

FIGS. 7A and 7B are diagrams schematically showing a part of a manufacturing process according to some embodiments;

FIG. 8 is a graph showing an amount of shrinkage of a slit width according to the temperature of heat applied to a cover layer;

FIGS. 9A and 9B are images of a portion of a folding pattern before and after a heat treatment process, respectively;

FIG. 10 is a plan view schematically showing an enlarged portion of a folding pattern and a cover layer, according to some embodiments;

FIG. 11 is a schematic cross-sectional view of a display apparatus according to some embodiments;

FIG. 12 is a schematic cross-sectional view of a display apparatus according to some embodiments;

FIG. 13 is a plan view schematically illustrating a display panel of a display apparatus according to some embodiments;

FIG. 14 is an equivalent circuit diagram schematically illustrating a pixel circuit of a display panel and a display element connected to the pixel circuit; and

FIG. 15 is a schematic cross-sectional view of the display apparatus of FIG. 13, taken along a line II-II′ in FIG. 13.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or any combination of a, b, and/or c.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the disclosure, and are not intended to preclude the possibility that one or more other features or elements may exist or may be added.

It will be understood that when a layer, region, or element is referred to as being formed on another layer, region, or element, it can be directly or indirectly formed on the other layer, region, or element. That is, for example, intervening layers, regions, or elements may be present.

Sizes of elements in the drawings may be exaggerated for convenience of explanation. For example, because sizes and thicknesses of elements in the drawings are arbitrarily illustrated for convenience of explanation, the following embodiments are not limited thereto.

In the present specification, “A and/or B” may include “A,” “B,” or “A and B.” In addition, in the present specification, “at least one of A and B” may include “A,” “B,” or “A and B.”

In the following embodiments, it will be understood that when a wire is referred to as “extending in a first direction or a second direction,” it cannot only extend in a linear shape, but also can extend in the first direction or the second direction in a zigzag or curved line.

In the following embodiments, “in a plan view” means that an object part is viewed from above. That is, in the disclosure, “in a plan view” may mean “when viewed from a direction perpendicular to a substrate 100.” In the following embodiments, “in a cross-sectional view” means that an object part is viewed from the side of a vertical cross section of the object part. In the following embodiments, when a first component is referred to as “overlapping” a second component, it means that the first component is positioned above or below the second component.

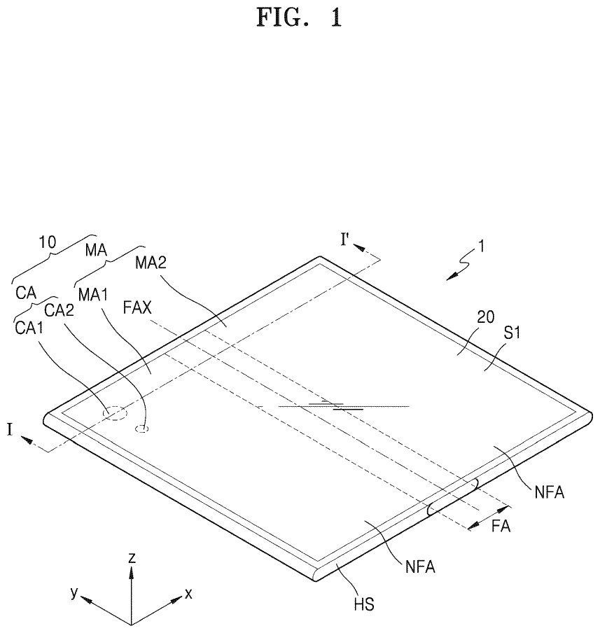

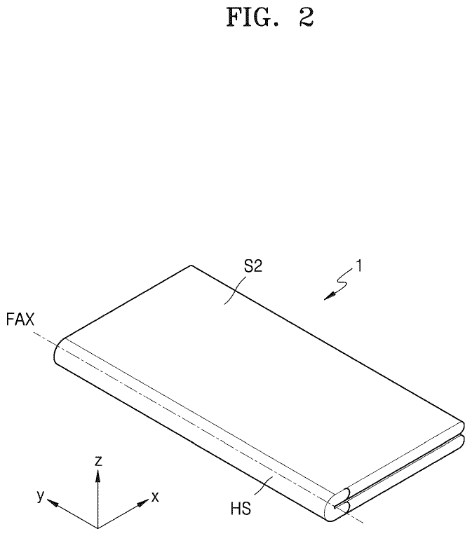

FIGS. 1 and 2 are perspective views each schematically illustrating a display apparatus 1 according to some embodiments. For example, FIG. 1 is a perspective view of the display apparatus 1 in an unfolded state, and FIG. 2 is a perspective view of the display apparatus 1 in a folded state.

As shown in FIGS. 1 and 2, the display apparatus 1 may include a housing HS, a display panel 10, and a cover window 20. The housing HS may include an inner surface defining an accommodation space. The housing HS may include a material having relatively high rigidity. For example, the housing HS may include a plurality of frames and/or plates including glass, plastic, metal, or a combination thereof. The housing HS may stably protect components of the display apparatus 1, which are accommodated in the inner space of the housing HS, from external impact.

The display panel 10 may display images. The display panel 10 may include a main area MA and a component area CA. According to some embodiments, the main area MA may be a main display area. A plurality of display elements may be arranged in the main area MA, and the plurality of display elements may emit light. Accordingly, the display panel 10 may display images through light emitted by the plurality of display elements. According to some embodiments, the display element may be an organic light-emitting diode including an organic emission layer. Alternatively, the display element may be a light-emitting diode (LED). A size of an LED may be in a micro scale or a nano scale. For example, the LED may be a micro-LED. Alternatively, the LED may be a nanorod LED. The nanorod LED may include gallium nitride (GaN). According to some embodiments, a color converting layer may be located above the nanorod LED. The color converting layer may include quantum dots. Alternatively, the display element may be a quantum dot LED including a quantum dot emission layer. Alternatively, the display element may be an inorganic LED including an inorganic semiconductor.

The component area CA may be an area displaying an image and an area overlapping a component for adding various functions. A plurality of display elements may be arranged in the component area CA. The component area CA may be at least partially surrounded by the main area MA. According to some embodiments, the component area CA may be entirely surrounded by the main area MA. According to some embodiments, the component area CA may include a first component area CA1 1 and a second component area CA2. According to some embodiments, any one of the first component area CA1 and the second component area CA2 may be omitted.

The cover window 20 may protect the display panel 10. According to some embodiments, the cover window 20 may be coupled to the housing HS to provide the appearance of the display apparatus 1. The cover window 20 may include an insulating panel. For example, the cover window 20 may include glass, plastic, or a combination thereof. The cover window 20 may define (or be located at) a front surface of the display apparatus 1.

The cover window 20 may include an optically transparent area. Accordingly, the display panel 10 may display images through a transparent area of the cover window 20, which is optically transparent. According to some embodiments, the transparent area may be surrounded by a bezel area of the cover window 20, and the shape of the transparent area may be defined by the bezel area. The light transmittance of the bezel area may be lower than the light transmittance of the transparent area. According to some embodiments, the bezel area may include an opaque material that blocks light. According to some embodiments, the bezel area may have a certain color. The bezel area may be defined by a bezel layer provided separately from a transparent substrate defining the transparent area, or may be defined by an ink layer inserted into or colored in the transparent substrate.

As shown in FIGS. 1 and 2, the display apparatus 1 may include a first surface S1 and a second surface S2 opposite to the first surface S1. The display apparatus 1 may display images on the first surface S1. According to some embodiments, the first surface S1 may be a front surface of the display apparatus 1. The second surface S2 may be a rear surface of the display apparatus 1. In some embodiments, the display apparatus 1 may also display images on the second surface S2.

The display apparatus 1 may be folded around a folding axis FAX crossing the first surface S1. According to some embodiments, the display apparatus 1 may be folded so that a portion of the first surface S1 and another portion of the first surface S1 face each other. According to some embodiments, the display apparatus 1 may be folded so that a portion of the second surface S2 and another portion of the second surface S2 face each other.

According to some embodiments, the folding axis FAX may extend in a second direction intersecting a first direction. According to some embodiments, the folding axis FAX may extend in the first direction. According to some embodiments, the first direction and the second direction may form an acute angle. According to some embodiments, the first direction and the second direction may form a right angle or an obtuse angle. Hereinafter, a case where the first direction (e.g., an x direction or −x direction) and the second direction (e.g., a y direction or −y direction) are orthogonal to each other is mainly described in detail.

FIGS. 1 and 2 show only one folding axis FAX, but according to some embodiments, the display apparatus 1 may include a plurality of folding axes FAX. Also, FIGS. 1 and 2 show that the folding axis FAX extends in the second direction (e.g., the y direction or −y direction), but according to some embodiments, the folding axis FAX may extend in the first direction (e.g., the x direction or −x direction) or a direction intersecting the first direction (e.g., the x direction or −x direction) and the second direction (e.g., the y direction or −y direction).

The display apparatus 1 may include the housing HS, the display panel 10, and the cover window 20. The display panel 10 may include the main area MA and the component area CA. According to some embodiments, the main area MA may include a first main area MA1 and a second main area MA2 with the folding axis FAX therebetween. The display panel 10 may include a folding area FA and a non-folding area NFA. The folding area FA may be a portion of the first main area MA1 adjacent to the folding axis FAX and a portion of the second main area MA2 adjacent to the folding axis FAX. The folding area FA may be folded around the folding axis FAX. The folding area FA may be between non-folding areas NFA. Unlike FIG. 1, one or more folding 1 areas FA may be provided. According to some embodiments, an area that is not folded is referred to as a non-folding area, but this is for convenience of explanation. The expression “non-folding” may include not only a case where a material is rigid due to lack of flexibility, but also a case where the material is flexible but is less flexible than that of a folding area, and a case where the material is flexible but is not folded.

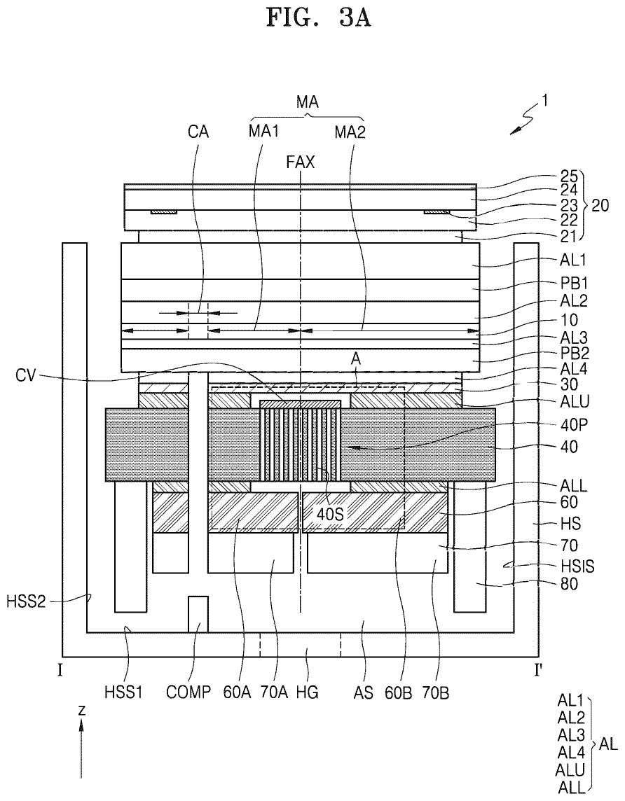

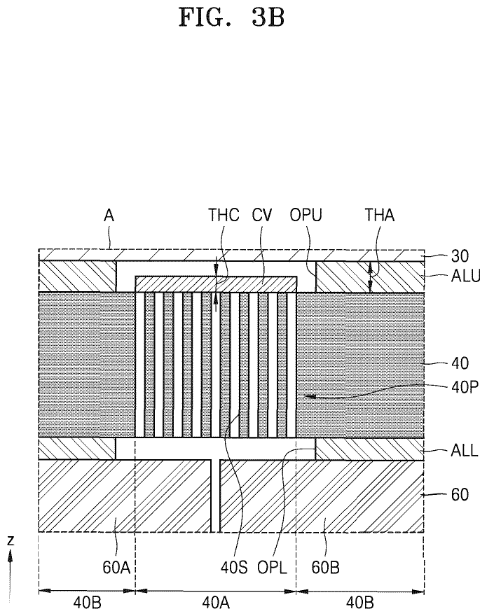

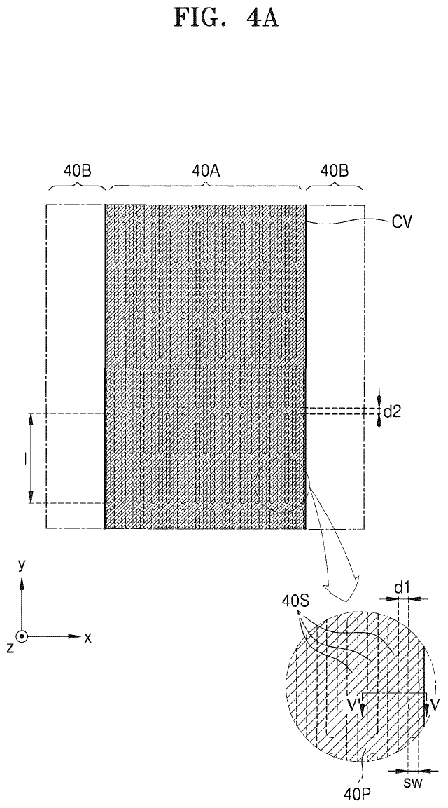

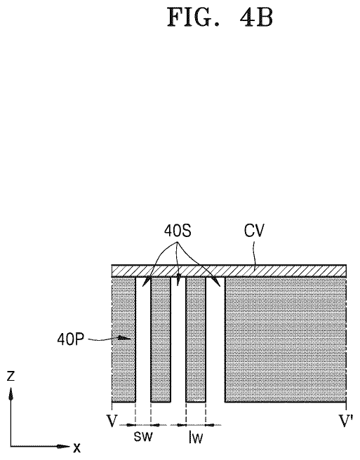

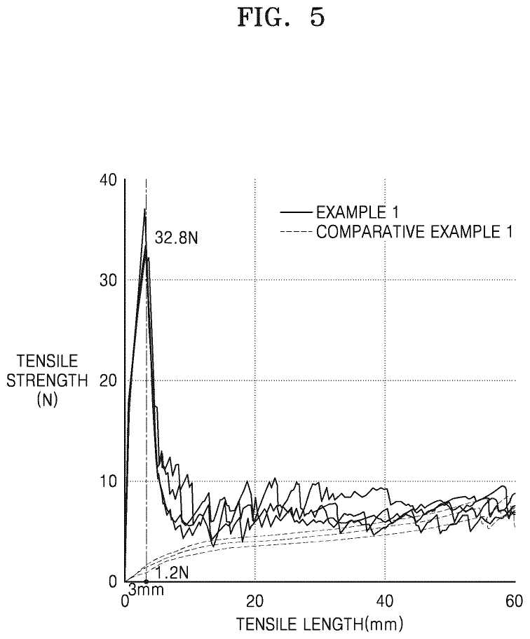

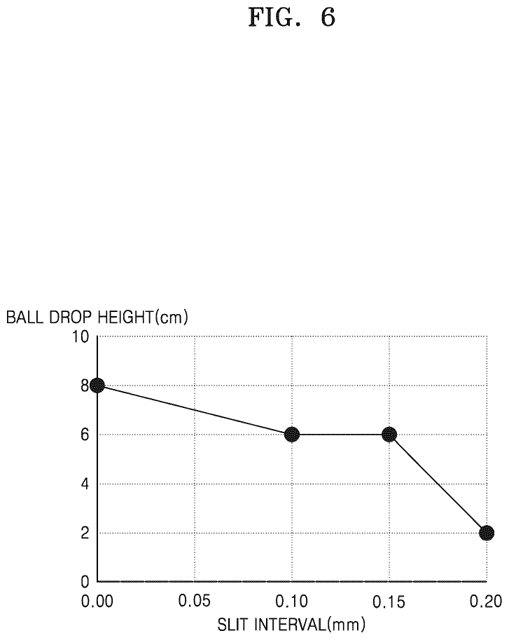

FIG. 3A is a schematic cross-sectional view of the display apparatus of FIG. 1, taken along a line I-I′ in FIG. 1, and FIG. 3B is a schematic cross-sectional view of a display apparatus according to some embodiments, which is an enlarged view of region A of FIG. 3A. FIGS. 4A and 4B are enlarged views of a portion of a folding pattern and a cover layer according to some embodiments, FIG. 5 is a graph showing a test result of tensile strength of a comparative example and an example, and FIG. 6 is a graph showing a test result of impact resistance according to a slit width.

Referring to FIG. 3A, the display apparatus 1 may include the housing HS, the display panel 10, the cover window 20, a first protective layer PB1, a second protective layer PB2, a support layer 30, a cover layer CV, a first plate 40, a second plate 60, a cushion layer 70, a waterproof layer 80, an adhesive layer AL, and a component COMP.

The housing HS may include an inner side surface HSIS defining an accommodation space AS. The inner side surface HSIS of the housing HS may not be a surface configuring the exterior of the display apparatus 1. According to some embodiments, the housing HS may have a rear surface HSS1 and a side surface HSS2. The rear surface HSS1 and the side surface HSS2 may not be surfaces configuring the exterior of the display apparatus 1. The display panel 10, the first protective layer PB1, the second protective layer PB2, the support layer 30, the cover layer CV, the first plate 40, the second plate 60, the cushion layer 70, the waterproof layer 80, the adhesive layer AL, and the component COMP may face the inner side surface HSIS of the housing HS.

Components of the display apparatus 1 may be arranged in the accommodation space AS. According to some embodiments, the display panel 10, the first protective layer PB1, the second protective layer PB2, the support layer 30, the cover layer CV, the first plate 40, the second plate 60, the cushion layer 70, the waterproof layer 80, the adhesive layer AL, and the component COMP may be arranged in the accommodation space AS. According to some embodiments, the housing HS may include a hinge area HG overlapping the folding axis FAX. Accordingly, the housing HS may be folded around the folding axis FAX.

The display panel 10 may be located below the cover window 20. According to some embodiments, the display panel 10 may be arranged in the accommodation space AS. Accordingly, the housing HS may protect the display panel 10. The display panel 10 may include the main area MA and the component area CA. According to some embodiments, the component area CA may overlap the component COMP. According to some embodiments, the main area MA may include the first main area MA1 and the second main area MA2 with the folding axis FAX therebetween.

The cover window 20 may be located on the display panel 10. According to some embodiments, the cover window 20 may be arranged over the housing HS. According to some embodiments, the cover window 20 may be connected to the housing HS. The cover window 20 may include a window 21, a window adhesive layer 22, an opaque layer 23, a window protective layer 24, and a hard coating layer 25. According to some embodiments, the window 21 may include ultra-thin glass. According to some embodiments, the window 21 may include a polymer resin.

The window protective layer 24 may protect the window 21 and may prevent or reduce the occurrence of scratches on an upper surface of the window 21. The window protective layer 24 may be located above the window 21. According to some embodiments, the window protective layer 24 may include a polymer resin. According to some embodiments, the window protective layer 24 may include an inorganic material.

The window adhesive layer 22 may be arranged between the window protective layer 24 and the window 21. The window adhesive layer 22 may adhere the window protective layer 24 to the window 21. According to some embodiments, the window adhesive layer 22 may be a pressure sensitive adhesive. According to some embodiments, the window adhesive layer 22 may be an optically clear adhesive.

The opaque layer 23 may be arranged between the window adhesive layer 22 and the window protective layer 24. In some embodiments, the opaque layer 23 may be a portion of the window protective layer 24. The opaque layer 23 may include an opaque material so that wires or circuits of the display panel 10 are not identified from the outside. Accordingly, the opaque layer 23 may be a bezel area of the cover window 20.

The hard coating layer 25 may be located on the window protective layer 24. The hard coating layer 25 may be the outermost layer of the cover window 20. The hard coating layer 25 may be the outermost layer of the display apparatus 1. The hard coating layer 25 is a layer that a user directly touches, and may provide a smooth and soft sense of touch. According to some embodiments, the hard coating layer 25 may include a polymer resin. According to some embodiments, the hard coating layer 25 may include an inorganic material.

The first protective layer PB1 may be arranged between the display panel 10 and the cover window 20. The first protective layer PB1 may protect the display panel 10 from external impact. According to some embodiments, the first protective layer PB1 may include a polymer resin. For example, the first protective layer PB1 may include at least one of polyethersulfone, polyacrylate, polyetherimide, polyethylene naphthalate, polyethylene terephthalate, polyphenylene sulfide, polyimide, polycarbonate, or cellulose acetate propionate. According to some embodiments, the first protective layer PB1 may include a material such as glass or quartz.

The second protective layer PB2 may be located below the display panel 10. According to some embodiments, the display panel 10 may be arranged between the first protective layer PB1 and the second protective layer PB2. The second protective layer PB2 may protect the display panel 10 from external impact. According to some embodiments, the second protective layer PB2 may include a polymer material. According to some embodiments, the second protective layer PB2 may include an inorganic material.

The support layer 30 may be located below the second protective layer PB2. According to some embodiments, the second protective layer PB2 may be arranged between the display panel 10 and the support layer 30. The support layer 30 may be located below the display panel 10 to support the display panel 10. The support layer 30 may include a polymer material. The support layer 30 may include a polymer resin such as polyethylene terephthalate or polyimide.

The first plate 40 may be located below the support layer 30. According to some embodiments, the support layer 30 may be arranged between the second protective layer PB2 and the first plate 40. The first plate 40 may be located below the support layer 30 to support the display panel 10. Accordingly, a degree that a center portion of the display panel 10 sags in a −z direction due to its weight is reduced, and thus the display panel 10 may not be easily damaged even when external impact is applied thereto.

The first plate 40 may include at least one of metal, glass, or plastic. According to some embodiments, the first plate 40 may include polyurethane. According to some embodiments, the first plate 40 may include carbon fiber reinforced plastic (CFRP). The first plate 40 may include a folding pattern 40P, and the cover layer CV may be located on the folding pattern 40P. Detailed descriptions of the folding pattern 40P of the first plate 40 and the cover layer CV are made below with reference to FIG. 3B.

The second plate 60 may be located below the first plate 40. That is, the first plate 40 may be arranged between the support layer 30 and the second plate 60. The second plate 60 may transfer heat generated by the display apparatus 1 to the outside. Also, the second plate 60 may protect the display apparatus 1 from external impact. According to some embodiments, the second plate 60 may include a material with high heat transfer rate. For example, the second plate 60 may include metal or graphite. The second plate 60 may be relatively thin when the second plate 60 includes graphite as compared when the second plate 60 includes metal.

According to some embodiments, a digitizer may be interposed between the first plate 40 and the second plate 60. The digitizer may include a body layer and/or a pattern layer. The digitizer may sense a signal input from an external electronic pen or the like through the pattern layer. For example, the digitizer may sense the intensity, direction, or the like of a signal input by an electronic pen or the like. In this case, the digitizer may include a first digitizer and a second digitizer, which are spaced apart from each other with respect to the folding axis FAX. Accordingly, damage to the digitizer when the display apparatus 1 is folded may be prevented or reduced.

The cushion layer 70 may be located below the second plate 60. The second plate 60 may be arranged between the first plate 40 and the cushion layer 70. The cushion layer 70 may prevent or reduce damage to the display apparatus 1 from external impact. For example, the thickness of components of the display apparatus 1 (in the z axis direction) should be thin such that the display apparatus 1 is able to be folded around the folding axis FAX. That is, the thickness of the display panel 10 (in the z axis direction) should be thin. However, when the thickness of the display panel 10 (in the z axis direction) is thin, the display panel 10 may be easily damaged by external impact. The cushion layer 70 may prevent or reduce damage to the display panel 10 due to external impact by absorbing external impact applied to the display panel 10.

According to some embodiments, the cushion layer 70 may include a material having viscoelasticity. For example, the cushion layer 70 may include at least one of polyurethane, polyacrylate, or polyethylene. For example, the cushion layer 70 may include at least one of a urethane-based resin, an acrylate-based resin, or an ethylene-based resin. The cushion layer 70 may be a single-layered structure of a multi-layered structure, and may include a foam material similar to a sponge. According to some embodiments, the cushion layer 70 may further include a pressure sensitive adhesive. According to some embodiments, the cushion layer 70 may include a first portion 70A and a second portion 70B, which are spaced apart from each other around the folding axis FAX.

The waterproof layer 80 may be arranged outside the second plate 60 and the cushion layer 70. The waterproof layer 80 may prevent or reduce damage to the components of the display apparatus 1 due to moisture by blocking or absorbing moisture introduced from the outside of the display apparatus 1. According to some embodiments, the waterproof layer 80 may include a tape and/or a sponge.

The adhesive layer AL may be arranged between a first component and a second component of the display apparatus 1. The adhesive layer AL may adhere the first component and the second component to each other. According to some embodiments, the adhesive layer AL may be a pressure sensitive adhesive. According to some embodiments, the adhesive layer AL may be an optically clear adhesive. The adhesive layer AL may include a first adhesive layer AL1, a second adhesive layer AL2, a third adhesive layer AL3, a fourth adhesive layer AL4, an upper adhesive layer ALU, and a lower adhesive layer ALL.

The first adhesive layer AL1 may be arranged between the first protective layer PB1 and the cover window 20. The first adhesive layer AL1 may adhere the first protective layer PB1 and the cover window 20 to each other. The second adhesive layer AL2 may be arranged between the first protective layer PB1 and the display panel 10. The second adhesive layer AL2 may adhere the first protective layer PB1 and the display panel 10 to each other. The third adhesive layer AL3 may be arranged between the display panel 10 and the second protective layer PB2. The third adhesive layer AL3 may adhere the display panel 10 and the second protective layer PB2 to each other. The fourth adhesive layer AL4 may be arranged between the second protective layer PB2 and the support layer 30. The fourth adhesive layer AL4 may adhere the second protective layer PB2 and the support layer 30 to each other. The upper adhesive layer ALU may be arranged between the support layer 30 and the first plate 40. The upper adhesive layer ALU may adhere the support layer 30 and the first plate 40 to each other. The lower adhesive layer ALL may be arranged between the first plate 40 and the second plate 60. The lower adhesive layer ALL may adhere the first plate 40 and the second plate 60 to each other.

Each of the fourth adhesive layer AL4, the support layer 30, the upper adhesive layer ALU, the first plate 40, the lower adhesive layer ALL, the second plate 60, and the cushion layer 70 may have a through hole overlapping the component area CA. In this case, sound transmittance and/or light transmittance from the outside to the component COMP may be increased. According to some embodiments, at least one of the fourth adhesive layer AL4, the support layer 30, the upper adhesive layer ALU, the first plate 40, the lower adhesive layer ALL, the second plate 60, or the cushion layer 70 may not have a through hole overlapping the component area CA. According to some embodiments, the second protective layer PB2 may be continuously arranged in the main area MA and the component area CA. In this case, the second protective layer PB2 may protect the display panel 10. According to some embodiments, the second protective layer PB2 may have a through hole overlapping the component area CA.

The component COMP may be arranged between the housing HS and the display panel 10. According to some embodiments, the component COMP may be attached to the housing HS. According to some embodiments, the component COMP may be arranged in the accommodation space AS. The component COMP may be an electronic module. For example, the electronic module may include a sensor receiving and using light, such as an infrared sensor, a camera capturing an image by receiving light, a sensor outputting and sensing light or sound to measure a distance or recognize a fingerprint or the like, a small lamp outputting light, and/or a speaker outputting sound. An electronic module using light may use light having various wavelengths, such as visible light, infrared light, and/or ultraviolet light.

According to some embodiments, the component COMP may include a light-emitting module and a light-receiving module. The light-emitting module and the light-receiving module may form an integral structure or a physically separated structure, and a pair of the light-emitting module and the light-receiving module may form one component COMP.

FIG. 3B is an enlarged view of the support layer 30, the upper adhesive layer ALU, the cover layer CV, the first plate 40, the lower adhesive layer ALL, and the second plate 60 shown in FIG. 3A.

Referring to FIG. 3B, the first plate 40 may include a first area 40A and a second area 40B. The first area 40A may correspond to the folding area FA (refer to FIG. 1) of the display panel 10 (refer to FIG. 1), and the second area 40B may correspond to a non-folding area NFA (refer to FIG. 1) of the display panel 10 (refer to FIG. 1). In a plan view, the first area 40A may overlap the folding area FA, and the second area 40B may overlap the non-folding area NFA.

The first plate 40 may include the folding pattern 40P in which a plurality of slits 40S are defined. The folding pattern 40P may include a rib and slits 40S, wherein the rib may be a portion of a body part of the first plate 40 in the first area 40A, and the slits 40S may be a through hole provided in the first plate 40. According to some embodiments, when the display apparatus 1 is folded, the folding pattern 40P may be folded around the folding axis FAX. The shape or length of the folding pattern 40P may be changed when the display apparatus 1 is folded. According to some embodiments, the folding pattern 40P may be provided on both sides of the folding axis FAX to be symmetrical.

The folding pattern 40P of the first plate 40 may be arranged in the first area 40A. An upper surface of the first plate 40 may have irregularities in the first area 40A where the folding pattern 40P is positioned. An upper surface of the first plate 40 in the second area 40B may be flat. The rib of the folding pattern 40P may include the same material as the first plate 40 in the second area 40B or may include a different material from that of the first plate 40 in the second area 40B.

The cover layer CV may be located on the first plate 40. The cover layer CV may be arranged in the first area 40A of the first plate 40. The cover layer CV may be arranged to overlap the folding pattern 40P of the first plate 40. According to some embodiments, when the display apparatus 1 is folded, the cover layer CV may be folded around the folding axis FAX. The shape and length of the cover layer CV may be changed when the display apparatus 1 is folded.

The cover layer CV may be arranged to be in direct contact with the upper surface of the folding pattern 40P and may cover the plurality of slits 40S. The cover layer CV may have an adhesive strength of 1 kg/inch or more at room temperature (about 25° C.), and an adhesive strength of about 0.3 kg/inch or more at high temperature and high humidity (about 60° C. and about 93% or more). The cover layer CV may include a material with small transformation amount (or small elastic force). Accordingly, the cover layer CV may strengthen its ability to respond to an external shear force applied to the display apparatus 1. The cover layer CV may prevent or reduce transformation of the folding pattern 40P due to shear stress. The cover layer CV may prevent or reduce instances of the folding pattern 40P sagging.

The graph of FIG. 5 shows a comparison in shear tensile strength and tensile length between Example 1 including the cover layer CV and a comparative example not including a cover layer. For example, when a force is applied to pull both ends of a display apparatus outward while the display apparatus is inclined at about 23 degrees, it shows an increased length of the display apparatus. Referring to the graph of FIG. 5, in Example 1, the display apparatus has an increased length of 3 mm when a force was increased to about 32.8 N, while in the comparative example, the display apparatus has an increased length of 3 mm with only a force of about 1.2 N. In other words, based on a tensile length of 3 mm, Example 1 may withstand a force of 32.8 N, and the comparative example may withstand a force of 1.2 N. That is, Example 1 including the cover layer CV may be more robust to an external shear force than the comparative example.

The upper adhesive layer ALU may be located on the first plate 40. The upper adhesive layer ALU may include an upper opening OPU corresponding to the first area 40A. The upper opening OPU may correspond to the cover layer CV. The upper adhesive layer ALU may be in direct contact with the upper surface of the first plate 40 in the second area 40B.

According to some embodiments, a thickness THC of the cover layer CV may be less than a thickness THA of the upper adhesive layer ALU. Each of the thickness THC of the cover layer CV and the thickness THA of the upper adhesive layer ALU may be 6 μm or less. The upper adhesive layer ALU may have the upper opening OPU corresponding to the cover layer CV, and the cover layer CV may be formed thinner than the upper adhesive layer ALU, and thus, a certain space may exist between the cover layer CV and the support layer 30. An upper surface of the cover layer CV may not be in contact with the upper adhesive layer ALU. Accordingly, when viewed from the front surface of the display apparatus 1, the folding pattern 40P including the plurality of slits 40S may not be visible to a user, and the folding characteristics of the display apparatus 1 may be improved.

The lower adhesive layer ALL may be located below the first plate 40. The lower adhesive layer ALL may include a lower opening OPL corresponding to the first area 40A. The lower opening OPL may correspond to the folding pattern 40P. The lower opening OPL may correspond to the cover layer CV. The lower adhesive layer ALL may be in direct contact with a lower surface of the first plate 40 in the second area 40B. According to some embodiments, the second plate 60 may include a second-1 plate 60A and a second-2 plate 60B, which are spaced apart from each other with respect to the folding axis FAX, and thus a portion of the lower surface of the folding pattern 40P may be exposed.

Because some embodiments include the cover layer CV covering the upper surface of the folding pattern 40P, even when the lower surface of the folding pattern 40P is exposed by the lower opening OPL of the lower adhesive layer ALL and a separation space between the second-1 plate 60A and the second-2 plate 60B, a foreign material or contaminant may be prevented from flowing into the display panel 10 through the plurality of slits 40S of the folding pattern 40P. That is, because the flow of a foreign material or contaminant may be prevented without a separate layer for sealing the lower surface of the folding pattern 40P, the thickness of the display apparatus may be relatively reduced.

Referring to FIGS. 4A and 4B, the plurality of slits 40S may be arranged in a y direction (longitudinal direction, first direction) and an x direction (width direction, second direction) perpendicular to the y direction. The plurality of slits 40S may have a length I in the y direction parallel to a folding axis of a folding area. For example, the plurality of slits 40S may each have a long oval shape in the y direction. According to some embodiments, as shown in FIG. 4A, the plurality of slits 40S having the same length may be spaced apart from each other in the x direction and the y direction in the first area 40A. A width Iw of the rib of the folding pattern 40P may be determined by a first distance d1 in the x direction and a second distance d2 in the y direction between the plurality of slits 40S.

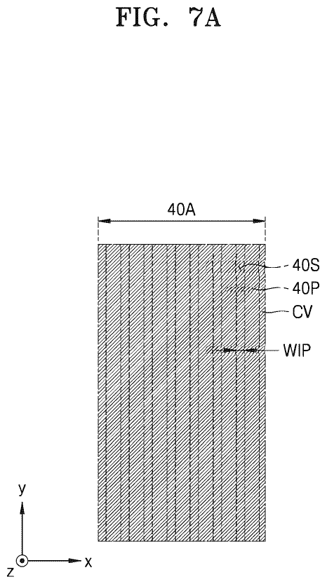

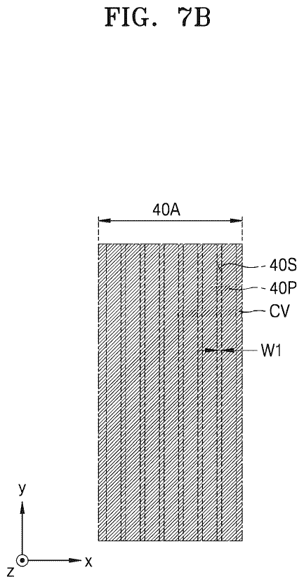

The embodiments are not limited to the arrangement of the plurality of slits 40S shown in FIG. 4A. According to some embodiments, the plurality of slits 40S may be arranged at regular or irregular intervals in the y direction and/or the x direction. For example, as shown in FIG. 7A, according to some embodiments, the folding pattern 40P may include the plurality of slits 40S arranged in parallel and spaced apart from each other in the x direction. The ribs and the plurality of slits 40S of the folding pattern 40P may be alternately arranged in the x direction. The plurality of slits 40S may have the same shape or different shapes.

A degree of flexibility of the first area 40A and impact resistance of the display apparatus may be determined by the length I and width sw of the slit 40S, and at least one of the first distance d1 or the second distance d2 between the slits 40S. FIG. 6 is a graph showing a ball drop test result according to slit width. The x axis of the graph represents the slit width, the y axis of the graph represents a ball drop height, and the ball drop height means a maximum height on a test that can be tolerated at the slit width. Referring to FIG. 6, when the slit width is 0.2 mm (200 μm), the ball drop height is about 2 cm, and when the slit width is 0.1 mm (100 μm), the ball drop height is about 6 cm. As the slit width approaches 0, the ball drop height approaches about 8 cm. As the slit width decreases, impact resistance improves.

According to some embodiments, the width sw of the slit 40S may be 100 μm or less or about 50 μm. According to some embodiments, the plurality of slits 40S of the folding pattern 40P may be formed through an etching process, a laser process, a blast process, or the like. However, when only the above process is applied, it may be difficult to reduce the width sw of the slit 40S to a certain interval or less.

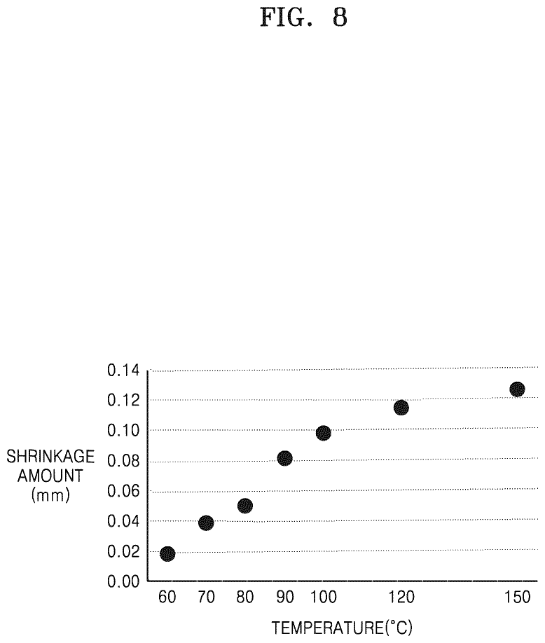

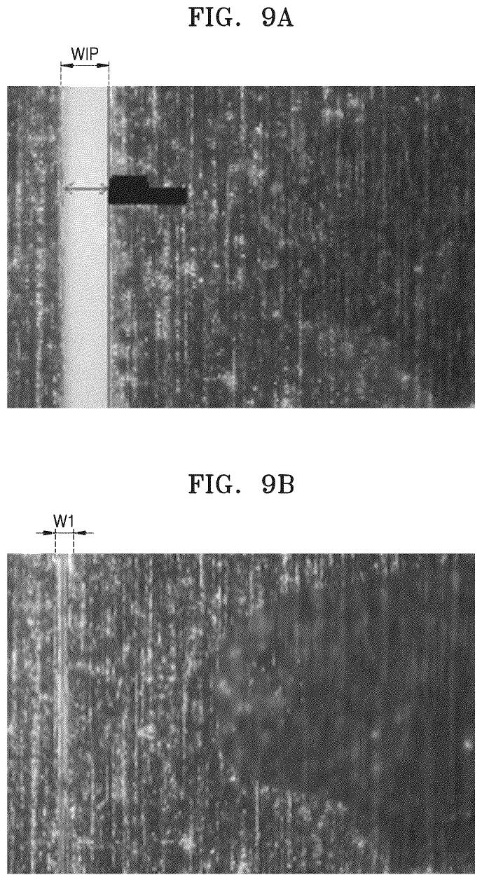

FIGS. 7A and 7B are diagrams schematically showing a part of a manufacturing process according to some embodiments, and FIG. 8 is a graph showing a shrinkage amount of a slit width according to a temperature of heat applied to a cover layer. FIGS. 9A and 9B are images of a portion of a folding pattern before and after a heat treatment process, respectively. For convenience of explanation, as shown in FIG. 7A, a case where the folding pattern 40P includes the plurality of slits 40S arranged in parallel and spaced apart from each other in the x direction is described as an example, but the embodiments of the disclosure are not limited thereto. The plurality of slits 40S may be arranged to be spaced apart from each other in the x direction and the y direction, as shown in FIG. 4A.

Referring to FIG. 7A, the folding pattern 40P in the first area 40A of a first plate may include a rib and the plurality of slits 40S each having a first preliminary width W1P. The first preliminary width W1P is the width of a slit 40S in the x direction 1 and may be a distance between ribs. According to some embodiments, the plurality of slits 40S may be formed through an etching process, a laser process, a blast process, or the like. According to some embodiments, the first preliminary width W1P may be 100 μm or more. The cover layer CV may be formed on the plurality of slits 40S each having the first preliminary width W1P. The cover layer CV may be in direct contact with the folding pattern 40P. The cover layer CV may be positioned on the plurality of slits 40S.

A heat treatment process may be performed on the cover layer CV located on the plurality of slits 40S each having the first preliminary width W1P. According to some embodiments, the heat treatment process may be a bake process. FIG. 7B shows the plurality of slits 40S and the cover layer CV after the heat treatment process. A method of manufacturing a display apparatus according to some embodiments may include forming the plurality of slits 40S each having the first preliminary width W1P in the first area 40A, forming the cover layer CV on the plurality of slits 40S, and applying heat to the cover layer CV to transform the plurality of slits 40S to have a first width W1 that is less than the first preliminary width W1P. The first width W1 corresponds to the width sw of the slit 40S described above with reference to FIG. 4B or the like. The first width W1 may be 100 μm or less or 50 μm or less. A difference between the first width W1 and the first preliminary width W1P may be at least about 20 μm but not more than about 200 μm.

According to some embodiments, the cover layer CV may include a heat-shrinkable material. According to some embodiments, the cover layer CV may include at least one of polyethylene terephthalate, low-density polyethylene, polyethylene, polypropylene, polyvinyl chloride, or polyvinylidene chloride. Because the cover layer CV includes a heat-shrinkable material, when heat is applied to the cover layer CV, the cover layer CV may shrink, and the folding pattern 40P therebelow may also shrink together. As the folding pattern 40P shrinks, the width sw (refer to FIG. 4B) of the slit 40S may also shrink.

The heat applied to the cover layer CV may be at least about 60° C. but not more than about 170° C. That is, the heat treatment process may be performed at a temperature of at least about 60° C. but not more than about 170° C. Referring to FIG. 8, as a temperature increases, a shrinkage amount of a slit width increases. When the temperature of the heat is 60° C. or more, the slit width may shrink by 0.02 mm (20 μm) or more. For example, when the temperature of the heat treatment is 100° C., the slit width may shrink by 0.1 mm (100 μm). This means that the slit width is formed to 200 μm through a process such as etching or the like and then shrinks to 100 μm. As described above, it may be difficult to form the slit width to a particular interval or less by using etching or the like, but according to some embodiments, the difficulty of a process may be reduced by forming a slit to have a first preliminary width and then apply heat to a cover layer having heat-shrinkable characteristics to shrink the first preliminary width to a first width. FIG. 9A shows a folding pattern before a heat treatment process, and FIG. 9B is an image showing the folding pattern after the heat treatment process. It shows that the first preliminary width W1P of FIG. 9A shrinks to the first width W1 of FIG. 9B, that is less than the first preliminary width W1P, after the heat treatment process.

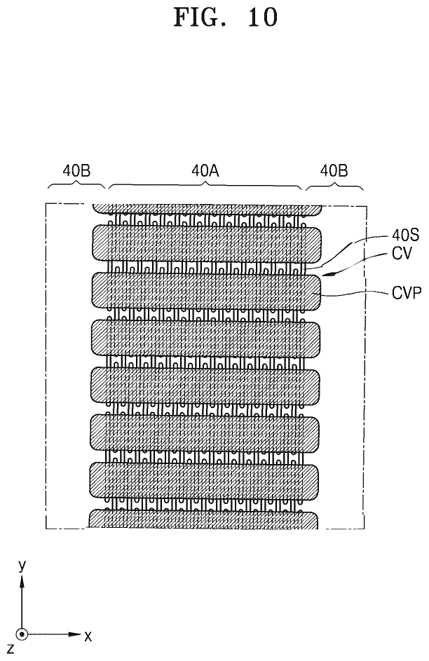

FIG. 10 is a plan view schematically showing an enlarged portion of a folding pattern and a cover layer according to some embodiments. In FIG. 10, the same reference numerals as those in FIGS. 3A to 4B refer to the same components, and thus redundant descriptions thereof are omitted.

Referring to FIG. 10, a first plate may include the first area 40A and the second area 40B, and the plurality of slits 40S and the cover layer CV may be positioned in the first area 40A. According to some embodiments, a portion of the cover layer CV may overlap the second area 40B.

According to some embodiments, the cover layer CV may include a plurality of cover patterns CVP. The plurality of cover patterns CVP may be arranged to be spaced apart from each other, as shown in FIG. 10. According to some embodiments, the plurality of cover patterns CVP may have areas connected to each other. The plurality of cover patterns CVP may have a shape extending in the x direction (the second direction). The plurality of cover patterns CVP may be arranged in the y direction (the first direction). That is plurality of cover patterns CVP may be arranged in the y direction and may each have a length in the x direction. Accordingly, the cover layer CV may expose a portion of a folding pattern, and the folding characteristics of the display apparatus may be improved.

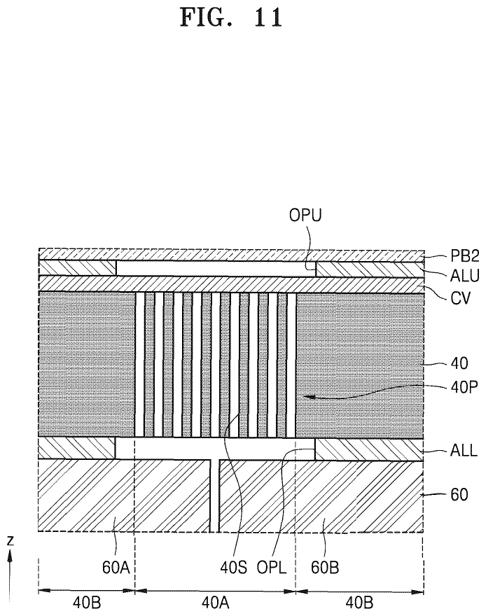

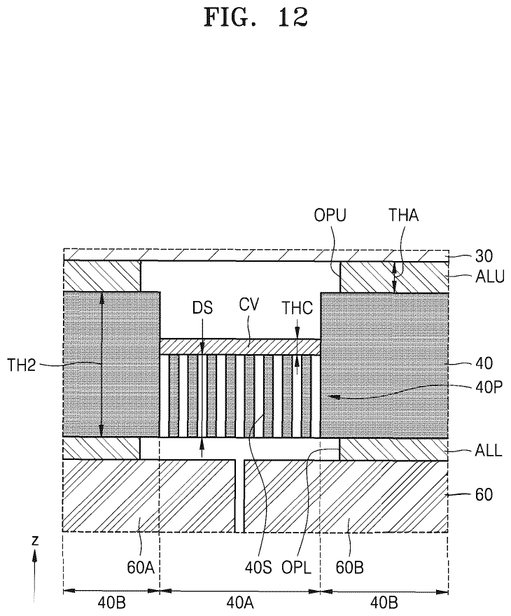

FIGS. 11 and 12 are schematic cross-sectional views of a display apparatus according to some embodiments. In FIGS. 11 and 12, the same reference numerals as those in FIGS. 3A and 3B refer to the same components, and thus redundant descriptions thereof are omitted.

Referring to FIG. 11, the cover layer CV may be arranged in the first area 40A and the second area 40B of the first plate 40. The cover layer CV may cover the folding pattern 40P of the first plate 40 as well as at least a portion of the first plate 40 in the second area 40B. According to some embodiments, the cover layer CV may include a light-blocking material to absorb light reflected by the components of the display apparatus. The upper adhesive layer ALU may overlap the second protective layer PB2 and the cover layer CV. The support layer 30 and the fourth adhesive layer AL4 shown in FIG. 3A may be omitted, and the cover layer CV may replace a function of the support layer 30 (refer to FIG. 3A). Accordingly, the thickness of the display apparatus may be reduced.

Referring to FIG. 12, a depth DS of each of the plurality of slits 40S of the folding pattern 40P may be less than a thickness TH2 of the second area 40B of the first plate 40. In other words, a thickness of the folding pattern 40P arranged in the first area 40A may be less than the thickness TH2 of the first plate 40 in the second area 40B in which the folding pattern 40P is not arranged. The cover layer CV may be located on the folding pattern 40P. Referring to FIG. 3B the upper adhesive layer ALU is formed to be thicker than the cover layer CV, so that the cover layer CV and the 1 support layer 30 may be spaced apart from each other. In FIG. 12, even when the thickness THA of the upper adhesive layer ALU is less than the thickness THC of the cover layer CV, the cover layer CV may be spaced apart from a layer located on the upper adhesive layer ALU. According to some embodiments, a sum of the thickness THC of the cover layer CV and the depth DS of the slit 40S may be less than the thickness TH2 of the first plate 40 in the second area 40B (THC+DS<TH2).

FIG. 12 shows that the upper adhesive layer ALU includes the upper opening OPU corresponding to the folding pattern 40P, but the disclosure is not limited thereto. According to some embodiments, the upper adhesive layer ALU may be arranged to overlap the folding pattern 40P in a plan view. The upper adhesive layer ALU may be arranged to overlap the cover layer CV in a plan view. When the depth DS of each of the plurality of slits 40S is less than the thickness TH2 of the first plate 40 in the second area 40B, even when the upper adhesive layer ALU is arranged to overlap the cover layer CV, the cover layer CV and the upper adhesive layer ALU may be arranged to be spaced apart from each other, and thus the visibility of the folding pattern 40P may be reduced.

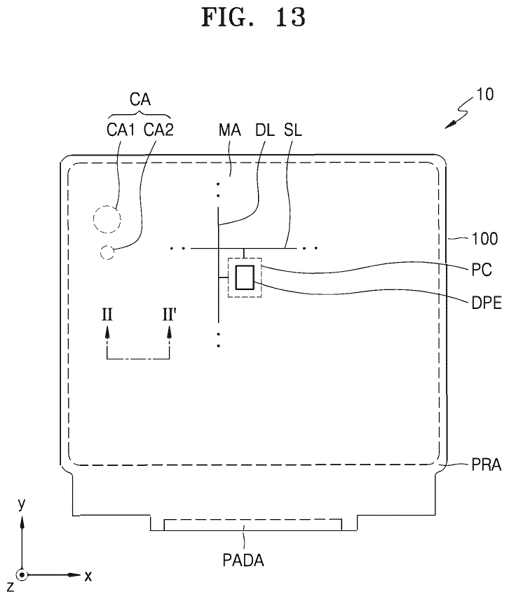

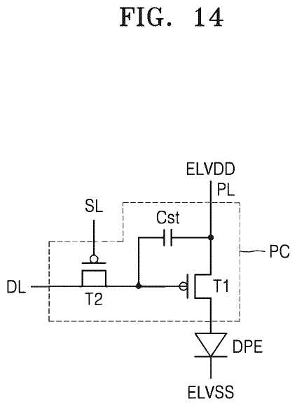

FIG. 13 is a plan view schematically illustrating the display panel 10 of a display apparatus according to some embodiments, and FIG. 14 is an equivalent circuit diagram schematically illustrating a pixel circuit PC of the display panel 10 and a display element DPE connected to the pixel circuit PC.

Referring to FIGS. 13 and 14, the display panel 10 may include the main area MA, the component area CA, and a peripheral area PRA. The display panel 10 may include a substrate 100, the pixel circuit PC, a scan line SL, a data line DL, a driving voltage line PL, and the display element DPE. According to some embodiments, the main area MA, the component area CA, and the peripheral area PRA may be defined on the substrate 100. In other words, the substrate 100 may include the main area MA, the component area CA, and the peripheral area PRA. Hereinafter, a case where the substrate 100 includes the main area MA, the component area CA, and the peripheral area PRA is mainly described in detail.

The pixel circuit PC and the display element DPE may overlap at least one of the main area MA or the component area CA. The pixel circuit PC may include a driving thin-film transistor T1, a switching thin-film transistor T2, and a storage capacitor Cst. The display element DPE may emit red, green, or blue light, or may emit red, green, blue, or white light.

The switching thin-film transistor T2 may be connected to the scan line SL and the data line DL, and be configured to transfer, to the driving thin-film transistor T1, a data voltage or a data signal input to the data line DL, according to a scan voltage or a scan signal input to the scan line SL.

The storage capacitor Cst may be connected to the switching thin-film transistor T2 and the driving voltage line PL, and may store a voltage corresponding to a difference between a voltage received from the switching thin-film transistor T2 and a first power supply voltage ELVDD supplied to the driving voltage line PL.

The driving thin-film transistor T1 may be connected to the driving voltage line PL and the storage capacitor Cst, and may control a driving current flowing from the driving voltage line PL to the display element DPE in accordance with a voltage value stored in the storage capacitor Cst. The display element DPE may emit light having a certain brightness according to the driving current. An opposite electrode (e.g., a cathode) of the display element DPE may supply a second power supply voltage ELVSS.

Although FIG. 14 shows that the pixel circuit PC includes two thin-film transistors and one storage capacitor, the pixel circuit PC may include three or more thin-film transistors.

The component area CA may be at least partially surrounded by the main area MA. According to some embodiments, the component area CA may be entirely surrounded by the main area MA. The component area CA may include a pixel area in 1 which the display element DPE is arranged and a transmission area in which the display element DPE is not arranged. Accordingly, the light transmittance of the display panel 10 in the component area CA may be higher than the light transmittance of the display panel 10 in the main area MA. According to some embodiments, the component area CA may include the first component area CA1 and the second component area CA2.

The peripheral area PRA may be arranged outside the main area MA. According to some embodiments, the peripheral area PRA may surround the main area MA. A scan driver providing a scan signal to the pixel circuit PC, a data driver providing a data signal, and a power supply line providing the first power supply voltage ELVDD and/or the second power supply voltage ELVSS may be arranged in the peripheral area PRA. The peripheral area PRA may include a pad area PADA. A pad may be arranged in the pad area PADA, and a display circuit board may be connected to the pad.

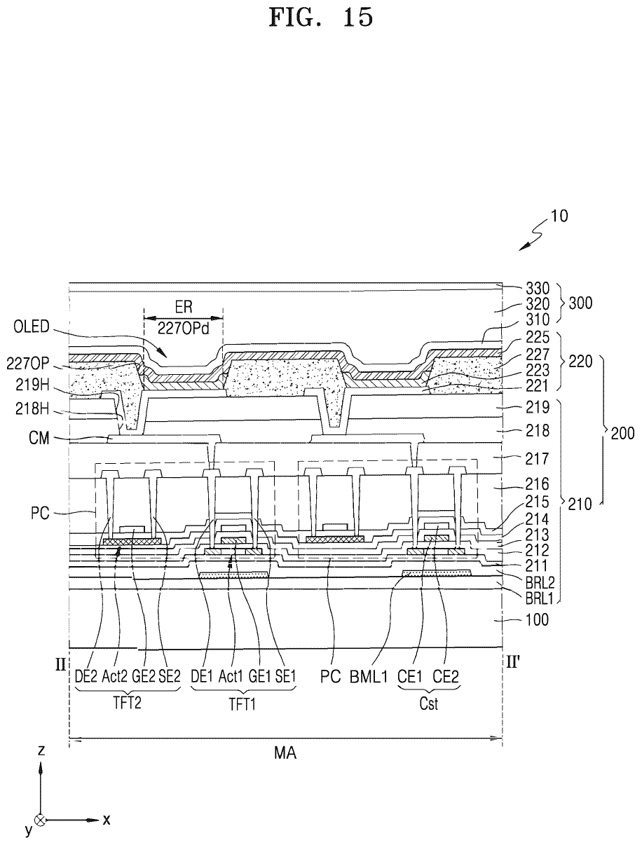

FIG. 15 is a schematic cross-sectional view of the display apparatus of FIG. 13, taken along a line II-II′ in FIG. 13. As shown in FIG. 15, the display panel 10 may include the substrate 100, a display layer 200, and an encapsulation layer 300. The substrate 100 may include glass or a polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like. According to some embodiments, the substrate 100 may have a multi-layered structure including a base layer and a barrier layer, wherein the base layer includes the polymer resin described above. The substrate 100 including the polymer resin may be flexible, rollable, or bendable.

The display layer 200 may be located on the substrate 100. The display layer 200 may include a pixel circuit layer 210 and a display element layer 220.

The pixel circuit layer 210 may include a first barrier layer BRL1, a first metal layer BML1, a second barrier layer BRL2, the pixel circuit PC, a connection electrode CM, and a plurality of insulating layers. The pixel circuit PC may include a first thin-film transistor TFT1, a second thin-film transistor TFT2, and a storage capacitor Cst. The first thin-film transistor TFT1 may include a first semiconductor layer Act1, a first gate electrode GE1, a first source electrode SE1, and a first drain electrode DE1. The second thin-film transistor TFT2 may include a second semiconductor layer Act2, a second gate electrode GE2, a second source electrode SE2, and a second drain electrode DE2. The storage capacitor Cst may include a first electrode CE1 and a second electrode CE2. The plurality of insulating layers may include a buffer layer 211, a first inorganic insulating layer 212, a second inorganic insulating layer 213, an intermediate insulating layer 214, a third inorganic insulating layer 215, a fourth inorganic insulating layer 216, a first organic insulating layer 217, a second organic insulating layer 218, and a third organic insulating layer 219.

The first barrier layer BRL1 may be located on the substrate 100. The first barrier layer BRL1 may include an inorganic material such as silicon oxide (SiO_{X}), silicon nitride (SiN_{X}), or silicon oxynitride (SiO_{X}N_{Y}).

According to some embodiments, the first barrier layer BRL1 may include amorphous silicon (a-Si). According to some embodiments, the first barrier layer BRL1 may include a single layer or a multi-layer, each including the above material. The first metal layer BML1 may be located on the first barrier layer BRL1.

The first metal layer BML1 may overlap the first thin-film transistor TFT1. The first metal layer BML1 may function as a lower protective metal protecting a layer overlapping the first metal layer BML1. According to some embodiments, the first metal layer BML1 may not overlap the second thin-film transistor TFT2. In some embodiments, the first metal layer BML1 may be applied with an electrostatic voltage or a signal. The first metal layer BML1 may more easily provide charges to a back channel of the pixel circuit PC. The first metal layer BML1 may include aluminum (AI), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu). According to some embodiments, the first metal layer BML1 may include doped amorphous silicon. The first metal layer BML1 may include a single layer or a multi-layer, each including the above material.

The second barrier layer BRL2 may be located on the first barrier layer BRL1. The second barrier layer BRL2 may include an inorganic material such as silicon oxide (SiO_{X}), silicon nitride (SiN_{X}), or silicon oxynitride (SiO_{X}N_{Y}). In some embodiments, the second barrier layer BRL2 may include amorphous silicon (a-Si). According to some embodiments, the second barrier layer BRL2 may include a single layer or a multi-layer, each including the above material.

The buffer layer 211 may be located on the second barrier layer BRL2. The buffer layer 211 may include an inorganic material, such as silicon oxide (SiO_{X}), silicon nitride (SiN_{X}), or silicon oxynitride (SiO_{X}N_{Y}), and may include a single layer or a multi-layer, each including the above inorganic material.

The first semiconductor layer Act1 may be located on the buffer layer 211. The first semiconductor layer Act1 may include a silicon semiconductor. According to some embodiments, the first semiconductor layer Act1 may include polysilicon. The first semiconductor layer Act1 may include a channel area, a drain area, and a source area, the drain area and the source area being respectively arranged on both sides of the channel area. According to some embodiments, the first semiconductor layer Act1 may include an organic semiconductor or an oxide semiconductor.

The first inorganic insulating layer 212 may be located on the first semiconductor layer Act1. The first inorganic insulating layer 212 may include an inorganic insulating material such as silicon oxide (SiO_{X}), silicon nitride (SiN_{X}), or silicon oxynitride (SiO_{X}N_{Y}). That is, the first inorganic insulating layer 212 may include at least one of silicon oxide (SiO_{X}), silicon nitride (SiN_{X}), or silicon oxynitride (SiO_{X}N_{Y}). According to some embodiments, the first inorganic insulating layer 212 may include aluminum oxide (Al₂O₃), titanium oxide (TiO₂), tantalum oxide (Ta₂O₅), hafnium oxide (HfO₂), or zinc oxide (ZnO).

The first gate electrode GE1 may be located on the first inorganic insulating layer 212. The first gate electrode GE1 may overlap the first semiconductor layer Act1. The first gate electrode GE1 may include Mo. The first gate electrode GE1 may include Al, Pt, Pd, Ag, Mg, Au, Ni, Nd, Ir, Cr, Ca, Mo, Ti, W, and/or Cu, and may include a single layer or a multi-layer, each including the above material.

The second inorganic insulating layer 213 may be located on the first gate electrode GE1. The second inorganic insulating layer 213 may include an inorganic insulating layer such as silicon oxide (SiO_{X}), silicon nitride (SiN_{X}), or silicon oxynitride (SiO_{X}N_{Y}). That is, the second inorganic insulating layer 213 may include at least one of silicon oxide (SiO_{X}), silicon nitride (SiN_{X}), or silicon oxynitride (SiO_{X}N_{Y}). According to some embodiments, the second inorganic insulating layer 213 may include aluminum oxide (Al₂O₃), titanium oxide (TiO₂), tantalum oxide (Ta₂O₅), hafnium oxide (HfO₂), or zinc oxide (ZnO).

The second electrode CE2 may be located on the second inorganic insulating layer 213. According to some embodiments, the second electrode CE2 may overlap the first gate electrode GE1. The second electrode CE2 and the first gate electrode GE1, which overlap each other with the second inorganic insulating layer 213 therebetween, may form the storage capacitor Cst. That is, the first gate electrode GE1 may function as the first electrode CE1 of the storage capacitor Cst. As such, the storage capacitor Cst may overlap the first thin-film transistor TFT1. According to some embodiments, the storage capacitor Cst may not overlap the first thin-film transistor TFT1. The second electrode CE2 may include Al, Pt, Pd, Ag, Mg, Au, Ni, Nd, Ir, Cr, Ca, Mo, Ti, W, and/or Cu, and may include a single layer or a multi-layer, each including the above material.

The intermediate insulating layer 214 may be located on the second electrode CE2. The intermediate insulating layer 214 may include an inorganic insulating material such as silicon oxide (SiO_{X}), silicon nitride (SiN_{X}), or silicon oxynitride (SiO_{X}N_{Y}). That is, the intermediate insulating layer 214 may include at least one of silicon oxide (SiO_{X}), silicon nitride (SiN_{X}), or silicon oxynitride (SiO_{X}N_{Y}). According to some embodiments, the intermediate insulating layer 214 may include aluminum oxide (Al₂O₃), titanium oxide (TiO₂), tantalum oxide (Ta₂O₅), hafnium oxide (HfO₂), or zinc oxide (ZnO).

The second semiconductor layer Act2 may be located on the intermediate insulating layer 214. That is, the second semiconductor layer Act2 may be located over the second inorganic insulating layer 213. The second semiconductor layer Act2 may include a channel area, a source area, and a drain area, wherein the source area and the drain area are respectively arranged on both sides of the channel area. The second semiconductor layer Act2 may include an oxide semiconductor. For example, the second semiconductor layer Act2 may include a zinc-oxide-based material, and may include Zn oxide, In—Zn oxide, Ga—In—Zn oxide, or the like. Alternatively, the second semiconductor layer Act2 may include an In—Ga—Zn—O (IGZO), In—Sn—Zn—O (ITZO), or In—Ga—Sn—Zn—O (IGTZO) semiconductor, which includes a metal such as In, Ga, and tin (Sn) in ZnO.

The source area and the drain area of the second semiconductor layer Act2 may be formed by adjusting a carrier concentration of an oxide semiconductor to make the source area and the drain area conductive. For example, the source area and the drain area of the second semiconductor layer Act2 may be formed by increasing the carrier concentration through a plasma treatment using a hydrogen-based gas, a fluorine-based gas, or a combination thereof on the oxide semiconductor.

The third inorganic insulating layer 215 may be located on the second semiconductor layer Act2. The third inorganic insulating layer 215 may include an inorganic insulating material, such as silicon oxide (SiO_{X}), silicon nitride (SiN_{X}), or silicon oxynitride (SiO_{X}N_{Y}). That is, the third inorganic insulating layer 215 may include at least one of silicon oxide (SiO_{X}), silicon nitride (SiN_{X}), or silicon oxynitride (SiO_{X}N_{Y}). According to some embodiments, the third inorganic insulating layer 215 may include aluminum oxide (Al₂O₃), titanium oxide (TiO₂), tantalum oxide (Ta₂O₅), hafnium oxide (HfO₂), or zinc oxide (ZnO).

The second gate electrode GE2 may be located on the third inorganic insulating layer 215. The second gate electrode GE2 may overlap the second semiconductor layer Act2. The second gate electrode GE2 may overlap the channel area of the second semiconductor layer Act2. The second gate electrode GE2 may include Al, Pt, Pd, Ag, Mg, Au, Ni, Nd, Ir, Cr, Ca, Mo, Ti, W, and/or Cu, and may include a single layer or a multi-layer, each including the above material.

The fourth inorganic insulating layer 216 may be located on the second gate electrode GE2. The fourth inorganic insulating layer 216 may include an inorganic insulating material, such as silicon oxide (SiO_{X}), silicon nitride (SiN_{X}), or silicon oxynitride (SiO_{X}N_{Y}). That is, the fourth inorganic insulating layer 216 may include at least one of silicon oxide (SiO_{X}), silicon nitride (SiN_{X}), or silicon oxynitride (SiO_{X}N_{Y}). According to some embodiments, the fourth inorganic insulating layer 216 may include aluminum oxide (Al₂O₃), titanium oxide (TiO₂), tantalum oxide (Ta₂O₅), hafnium oxide (HfO₂), or zinc oxide (ZnO). The fourth inorganic insulating layer 216 may include a single layer or a multi-layer, each including the above inorganic insulating layer.

The first source electrode SE1 and the first drain electrode DE1 may be located on the fourth inorganic insulating layer 216. Each of the first source electrode SE1 and the first drain electrode DE1 may be connected to the first semiconductor layer Act1. According to some embodiments, the first source electrode SE1 and the first drain electrode DE1 may be connected to the first semiconductor layer Act1 through contact holes of respective insulating layers. For example, the first source electrode SE1 and the first drain electrode DE1 may be connected to the first semiconductor layer Act1 through each of a contact hole of the first inorganic insulating layer 212, a contact hole of the second inorganic insulating layer 213, a contact hole of the intermediate insulating layer 214, a contact hole of the third inorganic insulating layer 215, and a contact hole of the fourth inorganic insulating layer 216. The contact hole of the first inorganic insulating layer 212, the contact hole of the second inorganic insulating layer 213, the contact hole of the intermediate insulating layer 214, the contact hole of the third inorganic insulating layer 215, and the contact hole of the fourth inorganic insulating layer 216 may overlap each other.

The second source electrode SE2 and the second drain electrode DE2 may be located on the fourth inorganic insulating layer 216. The second source electrode SE2 and the second drain electrode DE2 may be connected to the second semiconductor layer Act2. The second source electrode SE2 and the second drain electrode DE2 may be connected to the second semiconductor layer Act2 through each of a contact hole of the third inorganic insulating layer 215 and a contact hole of the fourth inorganic insulating layer 216.

Each of the first source electrode SE1, the first drain electrode DE1, the second source electrode SE2, and the second drain electrode DE2 may include a material with good conductivity. Each of the first source electrode SE1, the first drain electrode DE1, the second source electrode SE2, and the second drain electrode DE2 may include a conductive material including Mo, Al, Cu, Ti, or the like, and may include a multi-layer or a single layer, each including the above material. According to some embodiments, each of the first source electrode SE1, the first drain electrode DE1, the second source electrode SE2, and the second drain electrode DE2 may have a multi-layered structure of Ti/Al/Ti.

The first thin-film transistor TFT1 including the first semiconductor layer Act1 including a silicon semiconductor has high reliability, which may be used as a driving thin-film transistor to form the display panel 10 with high quality.

Because an oxide semiconductor has high carrier mobility and low leakage current, a voltage drop may not be large even when a driving time is long. That is, because color change of an image according to a voltage drop is not large even during low-frequency driving, the low-frequency driving is possible. In this way, because the oxide semiconductor has an advantage of having a small leakage current, leakage current may be prevented or reduced and power consumption may be relatively reduced at the same time by using an oxide semiconductor in at least one of other thin-film transistors other than the driving thin-film transistor. For example, the second thin-film transistor TFT2 may include the second semiconductor layer Act2 including an oxide semiconductor.

The first organic insulating layer 217 may be arranged to cover, the first source electrode SE1, the first drain electrode DE1, the second source electrode SE2, and the second drain electrode DE2. The first organic insulating layer 217 may include an organic material. For example, the first organic insulating layer 217 may include a general commercial polymer such as polymethyl methacrylate (PMMA) or polystyrene (PS), a polymer derivative having a phenol group, and an organic insulating material such as an acrylic polymer, an imide polymer, an aryl ether polymer, an amide polymer, a fluorine polymer, a p-xylene polymer, a vinyl alcohol polymer, and a mixture thereof.

The connection electrode CM may be located on the first organic insulating layer 217. The connection electrode CM may be connected to the first drain electrode DE1 or the first source electrode SE1 through a contact hole of the first organic insulating layer 217. The connection electrode CM may include a material having good conductivity. The connection electrode CM may include a conductive material including Mo, Al, Cu, Ti, or the like, and may include a multi-layer or a single layer, each including the above material. According to some embodiments, the connection electrode CM may have a multi-layered structure of Ti/Al/Ti.

The second organic insulating layer 218 and the third organic insulating layer 219 may be located on the connection electrode CM. Each of the second organic insulating layer 218 and the third organic insulating layer 219 may include an organic material. For example, at least one of the second organic insulating layer 218 or the third organic insulating layer 219 may include a general commercial polymer such as PMMA or PS, a polymer derivative having a phenol group, and an organic insulating material, such as an acrylic polymer, an imide polymer, an aryl ether polymer, an amide polymer, a fluorine polymer, a p-xylene polymer, a vinyl alcohol polymer, and a mixture thereof. Because the second organic insulating layer 218 and the third organic insulating layer 219 are sequentially stacked, the display element layer 220 may be located on the pixel circuit layer 210 with a flat surface. In some embodiments, the third organic insulating layer 219 may be omitted.

The display element layer 220 may be located on the pixel circuit layer 210. The display element layer 220 may include a display element, for example, an organic light-emitting diode OLED. A plurality of organic light-emitting diodes OLED may be provided in the main area MA. That is, the plurality of organic light-emitting diodes OLED may be arranged in the main area MA. The organic light-emitting diode OLED may include a pixel electrode 221, an emission layer 223, an opposite electrode 225, and a pixel defining layer 227.

The pixel electrode 221 may be located on the third organic insulating layer 219. The pixel electrode 221 may be connected to the connection electrode CM through a contact hole 218H of the second organic insulating layer 218 and a contact hole 219H of the third organic insulating layer 219. The pixel electrode 221 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). According to some embodiments, the pixel electrode 221 may include a reflective film including Ag, Mg, Al, Pt, Pd, Au, Ni, Nd, Ir, Cr, or a compound thereof. According to some embodiments, the pixel electrode 221 may further include a film including ITO, IZO, ZnO, or In₂O₃ above/below the reflective film mentioned above.

The pixel defining layer 227 may include an opening portion 227OP exposing at least a portion of the pixel electrode 221. The opening portion 227OP of the pixel defining layer 227 may define an emission area ER of the organic light-emitting diode OLED. The emission area ER of the organic light-emitting diode OLED may mean a sub-pixel. According to some embodiments, the pixel defining layer 227 may include a plurality of opening portions 227OP. The plurality of opening portions 227OP may define a plurality of emission areas ER of a plurality of organic light-emitting diodes OLED.

The pixel defining layer 227 may include an organic insulating material. According to some embodiments, the pixel defining layer 227 may include an inorganic insulating material such as silicon oxide (SiO_{X}), silicon nitride (SiN_{X}), or silicon oxynitride (SiON). According to some embodiments, the pixel defining layer 227 may include an organic insulating material and an inorganic insulating material. In some embodiments, the pixel defining layer 227 may include a light-blocking material, and may be provided in black. The light-blocking material may include carbon black, carbon nanotubes, a resin or paste including a black dye, metal particles, such as nickel, aluminum, molybdenum, and alloys thereof, metal oxide particles (e.g., chromium oxide), metal nitride particles (e.g., chromium nitride), or the like. When the pixel defining layer 227 includes the light-blocking material, reflection of external light by metal structures located below the pixel defining layer 227 may be reduced.

The emission layer 223 may be arranged in the opening portion 227OP of the pixel defining layer 227. The emission layer 223 may include a polymer organic material or a low-molecular-weight organic material, which emits light of a certain color. According to some embodiments, a first functional layer and a second functional layer may be respectively located below and above the emission layer 223. The first functional layer may include, for example, a hole transport layer (HTL) or an HTL and a hole injection layer (HIL). The second functional layer, as a component located on the emission layer 223, is optional. The second functional layer may include an electron transport layer (ETL) and/or an electron injection layer (EIL). Similar to the opposite electrode 225 to be described below, the first functional layer and/or the second functional layer may be a common layer entirely covering the substrate 100.

The opposite electrode 225 may be located on the emission layer 223. The opposite electrode 225 may include a conductive material having a low work function. For example, the opposite electrode 225 may include a (semi) transparent layer, the (semi) transparent layer including Ag, Mg, Al, Pt, Pd, Au, Ni, Nd, Ir, Cr, lithium (Li), Ca, alloys thereof, or the like. Alternatively, the opposite electrode 225 may further include a layer, such as ITO, IZO, ZnO, or In₂O₃, above the (semi) transparent layer including the above-stated material. In some embodiments, a capping layer may be further located on the opposite electrode 225. The capping layer may include lithium fluoride (LiF), an inorganic material, or/and an organic material.

The encapsulation layer 300 may be located on the display element layer 220. The encapsulation layer 300 may protect the display element layer 220. According to some embodiments, the encapsulation layer 300 may include at least one inorganic encapsulation layer and at least one organic encapsulation layer. The at least one inorganic encapsulation layer may include at least one inorganic material from among aluminum oxide (Al₂O₃), titanium oxide (TiO₂), tantalum oxide (Ta₂O₅), zinc oxide (ZnO), silicon oxide (SiO_{X}), silicon nitride (SiN_{X}), and silicon oxynitride (SiO_{X}N_{Y}). The at least one organic encapsulation layer may include a polymer-based material. The polymer-based material may include an acrylic resin, an epoxy resin, polyimide, polyethylene, or the like. According to some embodiments, the at least one organic encapsulation layer may include acrylate. According to some embodiments, the encapsulation layer 300 may include a first inorganic encapsulation layer 310, an organic encapsulation layer 320, and a second inorganic encapsulation layer 330, which are sequentially stacked.

For convenience, a display apparatus including an organic light-emitting diode as a display element is described above. However, embodiments of the disclosure may be applied to various display apparatuses, such as liquid crystal display apparatus, electrophoretic display apparatus, inorganic electroluminescence (EL) display apparatuses, or the like.

The display apparatus according to embodiments may be implemented as an electronic device such as a smartphone, a mobile phone, a smart watch, a navigation device, a game device, a television (TV), an automotive head unit, a notebook computer, a laptop computer, a tablet computer, a personal media play (PMP), a personal digital assistant (PDA), or the like. In addition, the electronic device may be a flexible device.

According to some embodiments as described above, a display apparatus with relatively improved impact resistance and a method of manufacturing the display apparatus may be implemented. The scope of embodiments according to the present disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a display panel in which a folding area and a non-folding area are defined;
a first plate on one surface of the display panel and comprising a first area and a second area, wherein the first area corresponds to the folding area of the display panel, and the second area corresponds to the non-folding area of the display panel; and
a cover layer between the first plate and the display panel and in direct contact with at least a portion of the first plate,
wherein the first area of the first plate comprises a plurality of slits each having a length in a first direction parallel to a folding axis of the folding area and being at least partially covered by the cover layer, and
a width of each of the plurality of slits in a second direction perpendicular to the first direction is 100 micrometers (μm) or less.

2. The display apparatus of claim 1, further comprising an upper adhesive layer between the first plate and the display panel and directing contact the first plate.

3. The display apparatus of claim 2, wherein the upper adhesive layer comprises an upper opening corresponding to the first area of the first plate, and
a thickness of the cover layer is less than a thickness of the upper adhesive layer.

4. The display apparatus of claim 2, wherein a depth of each of the plurality of slits is less than a thickness of the second area of the first plate.

5. The display apparatus of claim 1, wherein the plurality of slits are arranged in parallel and spaced apart from each other in the second direction.

6. The display apparatus of claim 1, further comprising:
a second plate below the first plate; and
a lower adhesive layer between the first plate and the second plate and comprising a lower opening corresponding to the first area of the first plate.

7. The display apparatus of claim 1, wherein the cover layer comprises a plurality of cover patterns extending in the second direction perpendicular to the first direction and spaced apart from each other in the first direction.

8. The display apparatus of claim 1, wherein the cover layer comprises a light-blocking material.

9. The display apparatus of claim 8, wherein, in a plan view, the cover layer overlaps the first area and the second area of the first plate.

10. The display apparatus of claim 1, wherein the cover layer comprises at least one of polyethylene terephthalate (PET), low-density polyethylene (LDPE), polyethylene (PE), polypropylene (PP), polyvinyl chloride (PVC), or polyvinylidene chloride (PVDC).

11. A method of manufacturing a display apparatus, the method comprising:
forming a display panel in which a folding area and a non-folding area are defined; and
forming a first plate on one surface of the display panel, the first plate comprising a first area and a second area, wherein the first area corresponds to the folding area of the display panel, and the second area corresponds to the non-folding area of the display panel,
wherein the forming of the first plate comprises:
forming a plurality of slits each having a first preliminary width, in the first area of the first plate;
forming a cover layer on the plurality of slits; and
applying heat to the cover layer to shrink the plurality of slits to have a first width that is less than the first preliminary width.

12. The method of claim 11, wherein the heat applied to the cover layer is at least 60° C. but not more than 170° C.

13. The method of claim 11, wherein a difference between the first preliminary width and the first width is at least 20 micrometers (μm) but not more than 200 μm.

14. The method of claim 11, wherein the first width is 50 μm or less.

15. The method of claim 11, wherein each of the plurality of slits has a length in a first direction in parallel to a folding axis of the folding area, and
the first width is a width in a second direction intersecting the first direction.

16. The method of claim 15, wherein the cover layer comprises a plurality of cover patterns arranged in the first direction and each having a length in the second direction.

17. The method of claim 11, further comprising forming an upper adhesive layer on the first plate and having an opening corresponding to the first area of the first plate,
wherein a thickness of the upper adhesive layer is greater than a thickness of the cover layer.

18. The method of claim 11, wherein a depth of each of the plurality of slits is less than a thickness of the second area of first plate.

19. The method of claim 11, wherein the cover layer comprises a light-blocking material.

20. The method of claim 11, wherein the cover layer comprises at least one of polyethylene terephthalate (PET), low-density polyethylene (LDPE), polyethylene (PE), polypropylene (PP), polyvinyl chloride (PVC), or polyvinylidene chloride (PVDC).
